(19) United States
(12) Patent Application Publication
(10) Pub. No.: US 2016/0276532 A1
(43) Pub. Date: Sep. 22, 2016

(54) SEMICONDUCTOR LIGHT EMITTING ELEMENT, METHOD FOR MANUFACTURING SAME, AND LIGHT EMITTING DEVICE

(71) Applicant: Kabushiki Kaisha Toshiba, Minato-ku (JP)

(72) Inventors: Kentaro MORI, Fujisawa (JP); Takeyuki Suzuki, Komatsu (JP); Mie Matsuo, Kamakura (JP); Masahiro Sekiguchi, Yokohama (JP); Koji Kaga, Komatsu (JP)

(73) Assignee: Kabushiki Kaisha Toshiba, Minato-ku (JP)

(21) Appl. No.: 15/061,398

(22) Filed: Mar. 4, 2016

(30) Foreign Application Priority Data
Mar. 17, 2015 (JP) 2015-052887

(51) Int. Cl. H01L 33/12; H01L 33/22; H01L 33/32; H01L 33/00; H01L 33/48; H01L 33/60; H01L 33/62; H01L 33/06; H01L 33/40

(52) U.S. Cl. CPC H01L 33/12; H01L 33/06; H01L 33/22; H01L 33/32; H01L 33/405; H01L 33/486; H01L 33/60; H01L 33/62; H01L 33/007; H01L 33/0079; H01L 2933/0016; H01L 2933/0066

(57) ABSTRACT

According to one embodiment, semiconductor light emitting element includes: a substrate having a first surface and a second surface on an opposite side of the first surface; an insulating layer provided on the second surface of the substrate; a first metal layer provided on the insulating layer; a semiconductor light emitting unit provided on the first metal layer, the semiconductor light emitting unit including a first semiconductor layer of a first conductivity type, a second semiconductor layer of a second conductivity type, and a light emitting layer provided between the first semiconductor layer and the second semiconductor layer, the second semiconductor layer being electrically connected to the first metal layer; and a first electrode layer provided on the first surface of the substrate, the first electrode layer extending in the substrate and in the insulating layer, and the first electrode layer being electrically connected to the first metal layer.

### CROSS-REFERENCE TO RELATED APPLICATIONS

This application is based upon and claims the benefit of priority from Japanese Patent Application No. 2015-052887, filed on Mar. 17, 2015; the entire contents of which are incorporated herein by reference.

### FIELD

Embodiments described herein relate generally to a semiconductor light emitting element, method for manufacturing the same, and a light emitting device.

### BACKGROUND

A semiconductor light emitting element such as LED (light emitting diode) includes a semiconductor light emitting unit including a p-type semiconductor layer, a light emitting layer, and an n-type semiconductor layer. The semiconductor light emitting unit is formed on e.g. a growth substrate by epitaxial growth technique. Then, the semiconductor light emitting unit may be bonded to another support substrate via a bonding layer, and the growth substrate may be stripped off.

In this case, the bonding layer is typically a metal layer. However, there may be a large difference between the thermal expansion coefficient of the metal and the thermal expansion coefficient of the support substrate. Then, the support substrate may be warped. The warpage of the support substrate may produce defects due to crystal strain in the semiconductor light emitting unit.

### BRIEF DESCRIPTION OF THE DRAWINGS

FIG. 1 is a schematic sectional view showing the main part of a semiconductor light emitting element according to a first embodiment;

FIGS. 2A to 5B are schematic sectional views showing the process for manufacturing the main part of the semiconductor light emitting element according to the first embodiment; and

FIG. 6A is a schematic sectional view showing the main part of a semiconductor light emitting element according to a second embodiment, FIG. 6B is a schematic sectional view showing the main part of a light emitting device including the semiconductor light emitting element according to the second embodiment.

### DETAILED DESCRIPTION

According to one embodiment, a semiconductor light emitting element includes: a substrate having a first surface and a second surface on an opposite side of the first surface; an insulating layer provided on the second surface of the substrate; a first metal layer provided on the insulating layer; a semiconductor light emitting unit provided on the first metal layer, the semiconductor light emitting unit including a first semiconductor layer of a first conductivity type, a second semiconductor layer of a second conductivity type, and a light emitting layer provided between the first semiconductor layer and the second semiconductor layer, the second semiconductor layer being electrically connected to the first metal layer; and a first electrode layer provided on the first surface of the substrate, the first electrode layer extending in the substrate and in the insulating layer, and the first electrode layer being electrically connected to the first metal layer.

Embodiments will now be described with reference to the drawings. In the following description, like members are labeled with like reference numerals, and the description of the members once described is omitted appropriately.

### First Embodiment

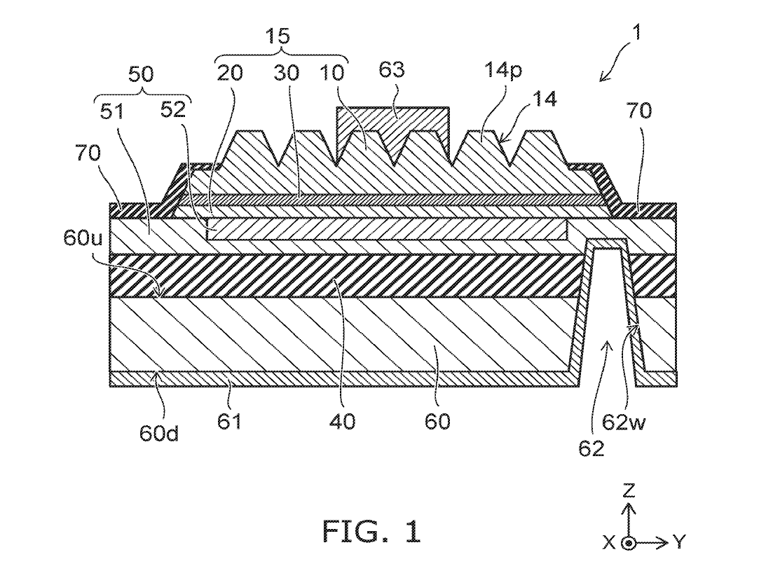

FIG. 1 is a schematic sectional view showing the main part of a semiconductor light emitting element according to a first embodiment.

The semiconductor light emitting element 1 according to the first embodiment includes a substrate 60, an insulating layer 40, a first metal layer 50, a semiconductor light emitting unit 15, a first electrode layer 61, a second electrode layer 63, and an insulating layer 70. The semiconductor light emitting unit 15 includes a first semiconductor layer 10, a second semiconductor layer 20, and a light emitting layer 30.

In the embodiment, the direction from the substrate 60 toward the semiconductor light emitting unit 15 is referred to as Z-axis direction. One direction perpendicular to the Z-axis direction is referred to as X-axis direction. The direction perpendicular to the Z-axis direction and the X-axis direction is referred to as Y-axis direction.

The substrate 60 is a support substrate of the semiconductor light emitting element 1. The substrate 60 has a lower surface 60d (first surface) and an upper surface 60u (second surface). The upper surface 60u of the substrate 60 lies on the opposite side from the lower surface 60d. The substrate 60 overlaps the semiconductor light emitting unit 15 as projected on the X-Y plane. The area of the substrate 60 is more than or equal to the area of the second semiconductor layer 20. The substrate 60 is e.g. a semiconductor substrate of e.g. silicon (Si).

The insulating layer 40 is provided on the upper surface 60u of the substrate 60. The first metal layer 50 is provided on the insulating layer 40. The insulating layer 40 is a bonding member for bonding the substrate 60 to the first metal layer 50. The insulating layer 40 includes e.g. silicon oxide (SiO₂). The first metal layer 50 includes a metal barrier film 51 and a metal reflective film 52.

The metal barrier film 51 is electrically connected to the first electrode layer 61. The metal barrier film 51 is part of the electrode. The metal barrier film 51 can be made of a metal having high adhesiveness to the insulating layer 40. This metal is e.g. Ti (titanium) or TiW (titanium-tungsten). The metal barrier film 51 may be e.g. a Ti film, Pt film, Au film, Ni film, Ag film, or a stacked film including one of these films.

The metal reflective film 52 is placed between the metal barrier film 51 and the semiconductor light emitting unit 15. The metal reflective film 52 is part of the electrode. The metal reflective film 52 is light reflective. The metal reflective film 52 is in ohmic contact with the second semiconductor layer 20. The metal reflective film 52 preferably has high reflectance to emission light. Increasing the reflectance of the metal reflective film 52 improves the light extraction efficiency. The light extraction efficiency refers to the proportion of the flux of light that can be extracted outside the semiconductor light emitting element 1 versus the total flux of light generated in the light emitting layer 30. The metal reflective film 52 includes at least one of e.g. aluminum (Al) and silver (Ag).

The semiconductor light emitting unit 15 is provided on the first metal layer 50. The semiconductor light emitting unit 15 includes a first semiconductor layer 10 of a first conductivity type (e.g., n-type), a second semiconductor layer 20 of a second conductivity type (e.g., p-type), and a light emitting layer 30. The light emitting layer 30 is provided between the first semiconductor layer 10 and the second semiconductor layer 20. The second semiconductor layer 20 is electrically connected to the first metal layer 50.

The first semiconductor layer 10, the second semiconductor layer 20, and the light emitting layer 30 each include a nitride semiconductor. The first semiconductor layer 10, the second semiconductor layer 20, and the light emitting layer 30 include e.g. AlₓGa_{1-x-y}In_{y}N (x≧0, y≧0, x+y≦1).

The first semiconductor layer 10 includes e.g. a Si-doped n-type GaN contact layer and a Si-doped n-type AlGaN cladding layer. The Si-doped n-type AlGaN cladding layer is placed between the Si-doped n-type GaN contact layer and the light emitting layer 30. The first semiconductor layer 10 may further include a GaN buffer layer. Then, the Si-doped n-type GaN contact layer is placed between the GaN buffer layer and the Si-doped n-type AlGaN cladding layer.

The light emitting layer 30 has e.g. a multiple quantum well (MQW) structure. The MQW structure includes e.g. a plurality of barrier layers and a plurality of well layers alternately stacked therein. The well layer is made of e.g. AlGaInN. The well layer is made of e.g. GaInN.

In the embodiment, the state of being stacked includes not only the state of being in direct contact, but also the state in which another component is interposed in between.

The barrier layer is made of e.g. Si-doped n-type AlGaN. The barrier layer is made of e.g. Si-doped n-type Al_{0.11}Ga_{0.89}N. The thickness of the barrier layer is e.g. 2 nm or more and 30 nm or less. Of the plurality of barrier layers, the barrier layer nearest to the semiconductor layer 20 may be different from the other barrier layers, and may be thicker or thinner.

The wavelength (peak wavelength) of light emitted from the light emitting layer 30 (emission light) is e.g. 210 nm or more and 700 nm or less. The peak wavelength of the emission light may be e.g. 370 nm or more and 480 nm or less.

The second semiconductor layer 20 includes e.g. a non-doped AlGaN spacer layer, a Mg-doped p-type AlGaN cladding layer, a Mg-doped p-type GaN contact layer, and a high-concentration Mg-doped p-type GaN contact layer. The Mg-doped p-type GaN contact layer is placed between the high-concentration Mg-doped p-type GaN contact layer and the light emitting layer 30. The Mg-doped p-type AlGaN cladding layer is placed between the Mg-doped p-type GaN contact layer and the light emitting layer 30. The non-doped AlGaN spacer layer is placed between the Mg-doped p-type AlGaN cladding layer and the light emitting layer 30. The second semiconductor layer 20 includes e.g. a non-doped Al_{0.11}Ga_{0.89}N spacer layer, a Mg-doped p-type Al_{0.28}Ga_{0.72}N cladding layer, a Mg-doped p-type GaN contact layer, and a high-concentration Mg-doped p-type GaN contact layer.

In the aforementioned semiconductor layers, the composition, the composition ratio, the kind of impurity, the impurity concentration, and the thickness are illustrative only, and can be variously modified.

The upper surface 14 of the semiconductor light emitting unit 15 is uneven. The unevenness includes a plurality of protrusions 14p. The distance between two adjacent protrusions 14p of the plurality of protrusions 14p is preferably more than or equal to the emission wavelength of the emission light emitted from the semiconductor light emitting unit 15. The emission wavelength is the peak wavelength in the semiconductor light emitting unit 15 (semiconductor layer 10). The unevenness thus provided improves the light extraction efficiency.

The planar shape of each of the plurality of protrusions 14p of the unevenness is e.g. rectangular. The unevenness is formed by e.g. anisotropic etching of the semiconductor layer 10 with chemicals (e.g., alkaline-based solution). Thus, the emission light emitted from the light emitting layer 30 is subjected to Lambertian reflection at the interface between the semiconductor layer 10 and the outside. The unevenness may be formed by dry etching using a mask. In this method, the unevenness can be formed as designed. This improves reproducibility and facilitates increasing the light extraction efficiency.

The semiconductor light emitting element 1 has a structure in which the first electrode layer 61 provided on the lower surface 60d side of the substrate 60 is not insulated from the second semiconductor layer 20 by the insulating layer 40, but electrically connected to the second semiconductor layer 20.

For instance, the first electrode layer 61 is provided on the lower surface 60d of the substrate 60, and extends in the substrate 60 and the insulating layer 40. The first electrode layer 61 is a back surface electrode of the semiconductor light emitting element 1. The first electrode layer 61 is part of the electrode of the semiconductor light emitting element 1. The first electrode layer 61 is electrically connected to the first metal layer 50. The first electrode layer 61 is electrically connected to the second semiconductor layer 20 via the first metal layer 50.

The substrate 60 and the insulating layer 40 are provided with a through hole 62 (hole) extending from the lower surface 60d of the substrate 60 to the first metal layer 50. The first electrode layer 61 is in contact with the lower surface 60d of the substrate 60, the inner wall 62w of the through hole 62, and the first metal layer 50. The material of the first electrode layer 61 is one of e.g. Ti, Cu, Ni, Au, Cr, Sn, In, Ag, and Al.

The through hole 62 and the first electrode layer 61 provided in the through hole 62 are not limited in number to those shown, but may be provided in a plurality. In this case, the through holes 62 and the first electrode layers 61 provided in the through holes 62 may be equally spaced below the semiconductor light emitting unit 15.

The second electrode layer 63 is provided on the first semiconductor layer 10 of the semiconductor light emitting unit 15. The second electrode layer 63 is an electrode of the semiconductor light emitting element 1. The second electrode layer 63 is a pad electrode. The insulating layer 70 is a protective layer for protecting part of the metal barrier film 51 and part of the semiconductor light emitting unit 15. The material of the second electrode layer 63 is one of e.g. Ti, Cu, Ni, Au, Cr, Sn, In, Ag, and Al.

The semiconductor light emitting element 1 may further include a sealing member (not shown) covering the semiconductor light emitting unit 15. This sealing member is made of e.g. resin. The sealing member may include a wavelength conversion body. The wavelength conversion body absorbs part of the emission light radiated from the semiconductor light emitting element 1 and emits light of a wavelength (peak wavelength) different from the wavelength (peak wavelength) of the emission light. The wavelength conversion body is made of e.g. phosphor.

A voltage is applied between the first electrode layer 61 and the second electrode layer 63. Thus, a voltage is applied to the light emitting layer 30. Accordingly, light is emitted from the light emitting layer 30.

The emitted light radiates primarily upward to the outside of the device. That is, part of the light emitted from the light emitting layer 30 travels upward and radiates to the outside of the device. On the other hand, another part of the light emitted from the light emitting layer 30 is efficiently reflected by the light-reflective metal reflective film 52, travels upward, and radiates to the outside of the device.

A method for manufacturing the semiconductor light emitting element is now described.

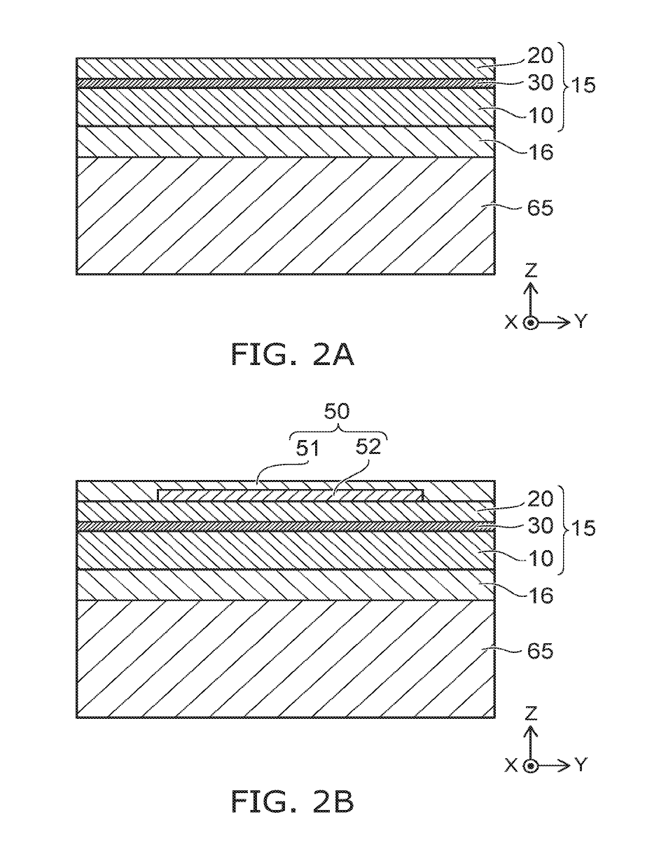

FIGS. 2A to 5B are schematic sectional views showing the process for manufacturing the main part of the semiconductor light emitting element according to the first embodiment.

For instance, as shown in FIG. 2A, a semiconductor layer 10, a light emitting layer 30, and a semiconductor layer 20 are epitaxially grown in this order on a growth substrate 65 (first substrate) via a buffer layer 16. Thus, a semiconductor light emitting unit 15 is formed on the growth substrate 65. The first semiconductor layer 10 is in contact with the buffer layer 16.

Here, the growth substrate 65 shown in FIG. 2A is a portion of the growth substrate in the wafer state before singulation. Actually, the growth substrate 65 extends in the X-direction and the Y-direction. The buffer layer 16 and the semiconductor light emitting unit 15 formed on the growth substrate 65 shown in FIG. 2A also extend in the X-direction and the Y-direction. In FIG. 2A, the growth substrate 65, the buffer layer 16, and the semiconductor light emitting unit 15 are shown as one chip portion of the semiconductor light emitting element 1.

Next, as shown in FIG. 2B, a first metal layer 50 in contact with the second semiconductor layer 20 is formed on the second semiconductor layer 20. For instance, a metal reflective film 52 is patterned on the second semiconductor layer 20. Furthermore, a metal barrier film 51 covering the metal reflective film 52 is formed on the second semiconductor layer 20.

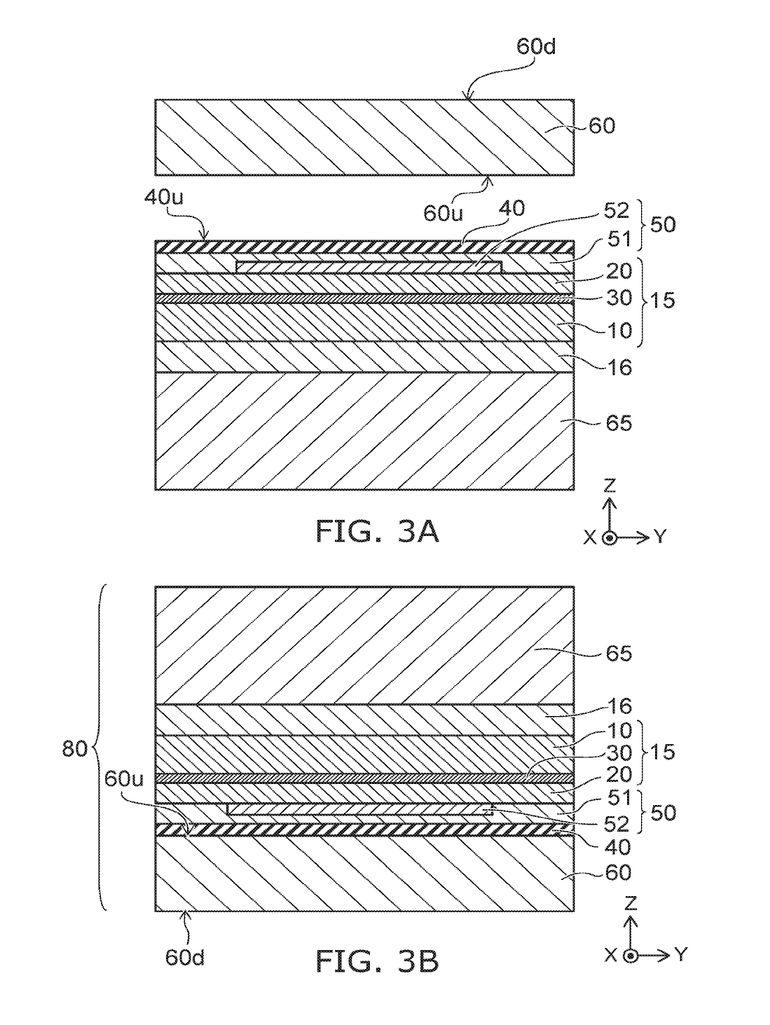

Next, as shown in FIG. 3A, an insulating layer 40 is formed on the first metal layer 50. The insulating layer 40 is in contact with the first metal layer 50. Next, the surface of the insulating layer 40 is activated by plasma irradiation in a vacuum. Next, the upper surface 60a of a substrate 60 (second substrate) is faced to the insulating layer 40. The surface 40u of the insulating layer 40 faced to the substrate 60 is subjected to planarization treatment. For instance, the surface 40u of the insulating layer 40 is made generally planar by CMP (chemical mechanical polishing) treatment.

Next, as shown in FIG. 3B, the upper surface 60a of the substrate 60 is bonded to the first metal layer 50 via the insulating layer 40. For instance, the insulating layer 40 is brought into contact with the upper surface 60a of the substrate 60. Then, the substrate 60 is pressed to the insulating layer at room temperature in an ambient atmosphere for approximately 10 seconds. Thus, the upper surface 60a of the substrate 60 is bonded to the insulating layer 40 by spontaneous bonding. Accordingly, the upper surface 60a of the substrate 60 is bonded to the first metal layer 50 via the insulating layer 40.

In this embodiment, the substrate 60 is bonded to the first metal layer 50 via the insulating layer 40. Then, the substrate 60 and the insulating layer 40 may be heated in an atmosphere (such as a nitrogen atmosphere and an inert gas atmosphere) of approximately 200° C. Here, the insulating layer 40, the first metal layer 50, the semiconductor light emitting unit 15, and the buffer layer 16 sandwiched by the substrate 60 and the growth substrate 65 are referred to as stacked body 80. In this embodiment, this stacked body 80 is previously prepared in a plurality. The plurality of stacked bodies 80 may be collectively subjected to heating treatment at approximately 200° C. This significantly reduces the heating time per one chip (one semiconductor light emitting element after singulation) in the heating treatment at approximately 200° C.

Then, the growth substrate 65 is removed from the buffer layer 16. Furthermore, the buffer layer 16 is removed from the semiconductor light emitting unit 15 (not shown).

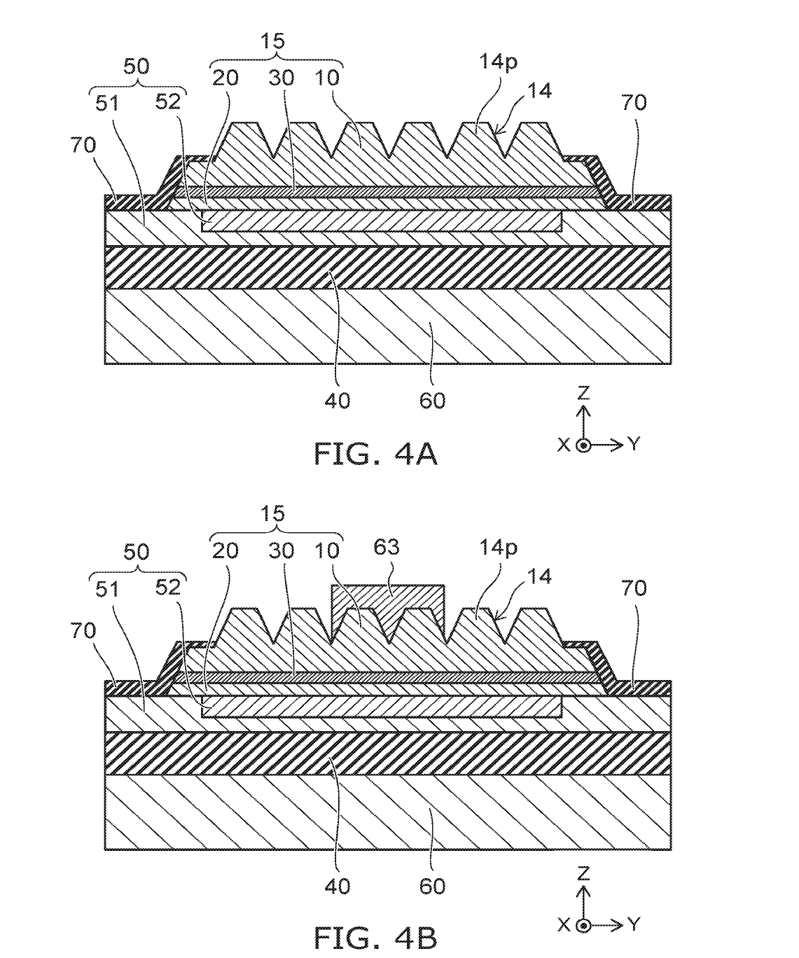

Next, as shown in FIG. 4A, protrusions 14p are formed at the upper surface 14 of the semiconductor layer 10 by e.g. etching. Furthermore, an insulating layer 70 is formed on the metal barrier film 51, the sidewall 15w of the semiconductor light emitting unit 15, and part of the upper surface 14 of the semiconductor light emitting unit 15 continued to the sidewall 15w of the semiconductor light emitting unit 15.

Next, as shown in FIG. 4B, a second electrode layer 63 is formed on the first semiconductor layer 10 by lithography and RIE (reactive ion etching).

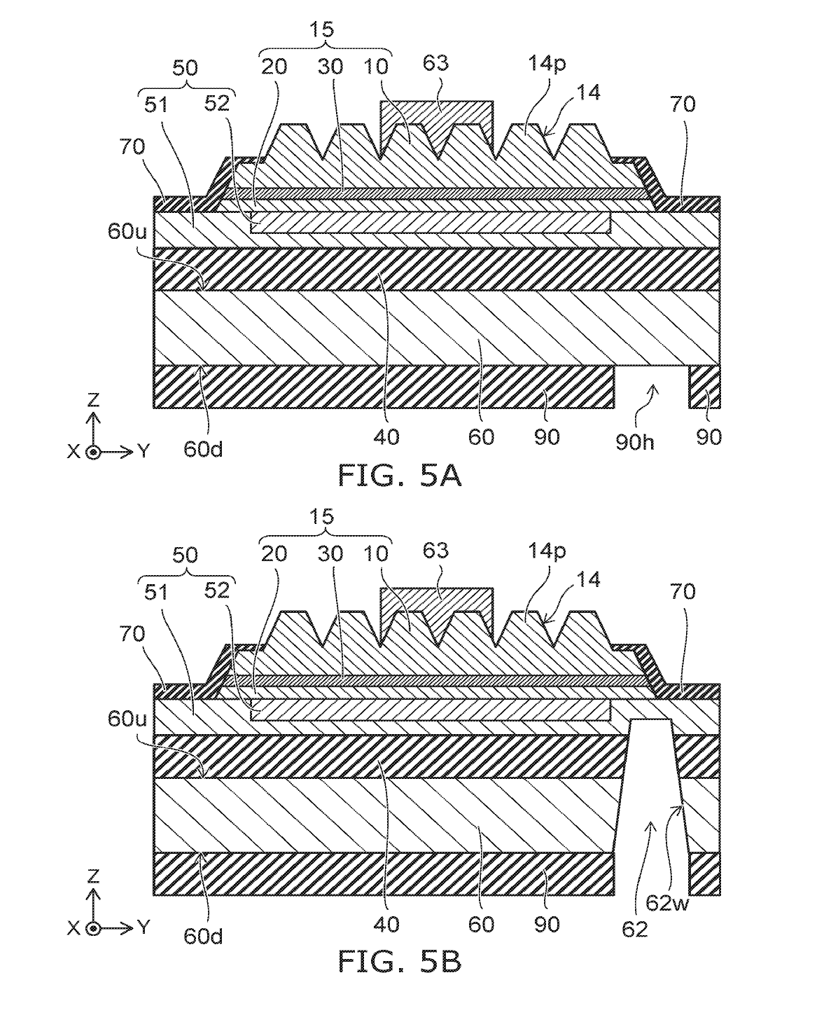

Next, as shown in FIG. 5A, a mask layer 90 is patterned by lithography and RIE on the lower surface 60d of the substrate 60.

Next, as shown in FIG. 5B, the lower surface 60d of the substrate 60 exposed from the mask layer 90 is etched by RIE. Thus, a through hole 62 extending from the lower surface 60d of the substrate 60 to the first metal layer 50 is formed in the substrate 60 and the insulating layer 40. Then, a first electrode layer 61 in contact with the lower surface 60d of the substrate 60, the inner wall 62w of the through hole 62, and the first metal layer 50 is formed as shown in FIG. 1. Furthermore, the substrate 60, the insulating layer 40, the first metal layer 50, and the insulating layer 70 are diced. Thus, the substrate 60 in the wafer state is singulated.

Here, consider the case where the bonding member connecting the substrate 60 with the first metal layer 50 is not an insulating layer 40, but a metal layer of e.g. copper (Cu).

In this case, the difference between the thermal expansion coefficient of the metal and the thermal expansion coefficient of the substrate 60 is larger than the difference between the thermal expansion coefficient of the insulating layer 40 and the thermal expansion coefficient of the substrate 60. Then, the substrate 60 may be warped. The warpage of the substrate 60 applies a stress to the semiconductor light emitting unit 15. This may produce defects due to crystal strain in the semiconductor light emitting unit 15. Furthermore, when the substrate 60 is warped, the substrate 60 is held by the transport arm less easily.

The bonding member of the metal layer is formed by laminating a metal layer provided on the substrate 60 side with a metal layer provided on the semiconductor light emitting unit 15 side. Here, if the opposed surfaces of the two metal layers are significantly uneven before lamination, then voids occur in the bonding member after lamination. The occurrence of voids may crack the bonding member starting from the void. Furthermore, lamination of two metal layers is performed by heating treatment at reduced pressure for several ten minutes. Thus, a longer time is required for the bonding process.

Furthermore, a dicing blade is used to singulate the semiconductor light emitting element 1. However, contact of the dicing blade with the metal layer different in material from the substrate 60 (e.g., silicon substrate) accelerates wear of the dicing blade. The metal may bite into the dicing blade. This degrades the cutting power of the dicing blade. Then, chipping defects may occur in the substrate 60.

In contrast, in the first embodiment, the bonding member connecting the substrate 60 with the first metal layer 50 is the insulating layer 40.

Thus, the difference between the thermal expansion coefficient of the insulating layer 40 and the thermal expansion coefficient of the substrate 60 is smaller than the difference between the thermal expansion coefficient of the metal and the thermal expansion coefficient of the substrate 60. Accordingly, the substrate 60 does not tend to be warped. Thus, the semiconductor light emitting unit 15 is less likely to be subjected to stress. Accordingly, defects are less likely to occur in the semiconductor light emitting unit 15. Furthermore, the substrate 60 is held by the transport arm more easily.

The surface 40u of the insulating layer 40 is generally planarized by e.g. CMP and then bonded to the substrate 60. Thus, voids are less likely to occur in the insulating layer 40. Accordingly, cracks are less likely to occur in the bonding member.

Bonding of the insulating layer 40 to the substrate 60 is finished in an ambient atmosphere within several ten seconds. This significantly reduces the time required for the bonding process.

The insulating layer 40 (e.g., silicon oxide) includes the same chemical element (e.g., silicon) as the substrate 60 (e.g., silicon substrate). Thus, the dicing blade in contact with the insulating layer 40 is less likely to wear. Furthermore, no metal bites into the dicing blade. Thus, the cutting power of the dicing blade is maintained. Accordingly, chipping defects are less likely to occur in the substrate 60.

### Second Embodiment

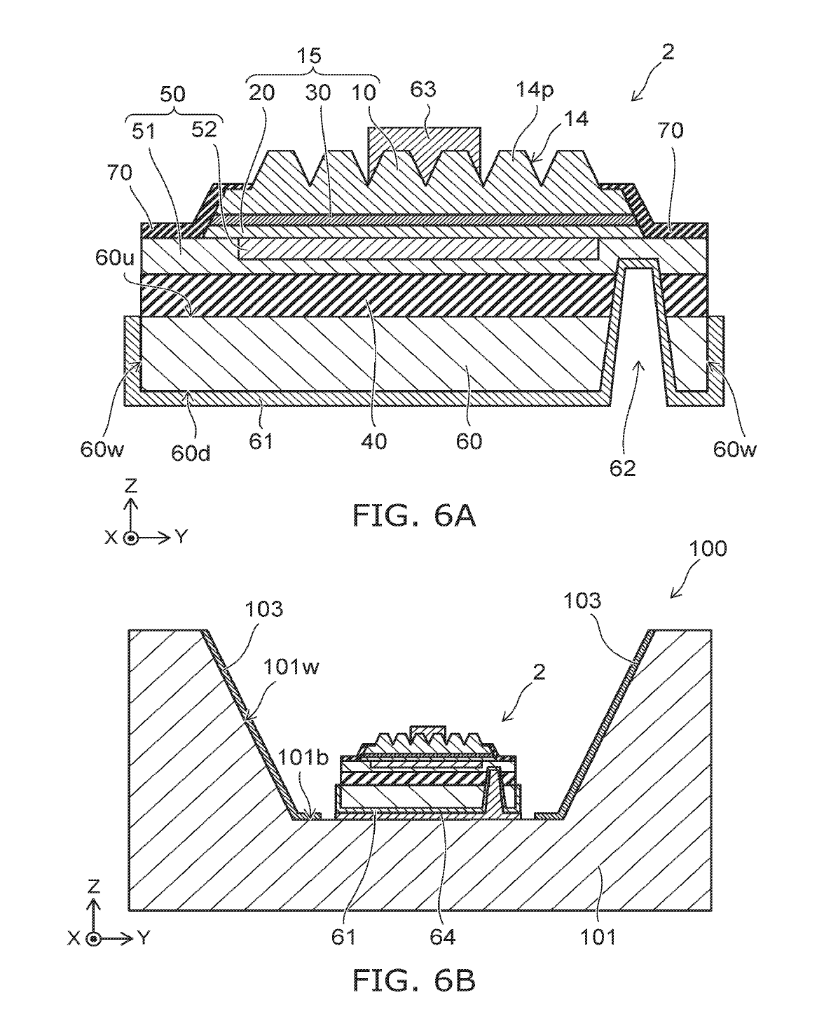

FIG. 6A is a schematic sectional view showing the main part of a semiconductor light emitting element according to a second embodiment. FIG. 6B is a schematic sectional view showing the main part of a light emitting device including the semiconductor light emitting element according to the second embodiment.

In the semiconductor light emitting element 2 shown in FIG. 6A, the first electrode layer 61 is in contact with the substrate 60 from the lower surface 60d of the substrate 60 to the side surface 60w (third surface) continued to the lower surface 60d and the upper surface 60u of the substrate 60. This first electrode layer 61 provided on the side surface 60w functions as a light reflective film besides the electrode.

For instance, FIG. 6B shows a light emitting device 100 provided with the semiconductor light emitting element 2. The semiconductor light emitting element 2 further includes a second metal layer 64. The second metal layer 64 is provided on the lower surface 60d of the substrate 60 and in the through hole 62 via the first electrode layer 61. The second metal layer 64 is electrically connected to the first electrode layer 61.

The semiconductor light emitting element 2 is mounted in a resin casing 101. A reflector 103 is provided on at least part of the sidewall 101w and at least part of the bottom part 101b in the resin casing 101. The reflector 103 reflects light emitted from the light emitting layer 30. This light is reflected by the reflector 103 at e.g. total reflection or high reflectance. The material and structure of the reflector 103 are not particularly limited. The material may be a metal having high reflection characteristics. Alternatively, for efficient total reflection, the reflector 103 may be made of a dielectric or a dielectric stacked structure having low absorptance and low refractive index, or a fine structure with optical design, or a combination thereof.

In the light emitting device 100, light is emitted from the light emitting layer 30. The light may be reflected by the reflector 103 and directed to the side surface 60w of the substrate 60. Then, the light is reflected again by the first electrode layer 61 provided on the side surface 60w. That is, the light reflected by the reflector 103 is less likely to be absorbed in the substrate 60. Thus, the light reflected by the reflector 103 is easily extracted out of the resin casing 101. This further improves the light emission efficiency. Furthermore, particles for scattering this light may be dispersed in the resin casing 101. The light emitting device 100 may be provided with the semiconductor light emitting element 1.

In the embodiments, the “nitride semiconductor” includes semiconductors of the chemical formula BₓIn_{y}Al_{z}Ga_{1-x-y-z}N (0≦x≦1, 0≦y≦1, 0≦z≦1, x+y+z≦1) of any compositions with the composition ratios x, y, and z varied in the respective ranges. Furthermore, the “nitride semiconductor” also includes those of the above chemical formula further containing group V elements other than N (nitrogen), those further containing various elements added to control various material properties such as conductivity type, and those further containing various unintended elements.

The embodiments have been described above with reference to examples. However, the embodiments are not limited to these examples. More specifically, these examples can be appropriately modified in design by those skilled in the art. Such modifications are also encompassed within the scope of the embodiments as long as they include the features of the embodiments. The components included in the above examples and the layout, material, condition, shape, size and the like thereof are not limited to those illustrated, but can be appropriately modified.

Furthermore, the components included in the above embodiments can be combined as long as technically feasible. Such combinations are also encompassed within the scope of the embodiments as long as they include the features of the embodiments. In addition, those skilled in the art could conceive various modifications and variations within the spirit of the embodiments. It is understood that such modifications and variations are also encompassed within the scope of the embodiments.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor light emitting element comprising:
a substrate having a first surface and a second surface on an opposite side of the first surface;
an insulating layer provided on the second surface of the substrate;
a first metal layer provided on the insulating layer;
a semiconductor light emitting unit provided on the first metal layer, the semiconductor light emitting unit including a first semiconductor layer of a first conductivity type, a second semiconductor layer of a second conductivity type, and a light emitting layer provided between the first semiconductor layer and the second semiconductor layer, the second semiconductor layer being electrically connected to the first metal layer; and
a first electrode layer provided on the first surface of the substrate, the first electrode layer extending in the substrate and in the insulating layer, and the first electrode layer being electrically connected to the first metal layer.

2. The element according to claim 1, wherein a chemical element included in the insulating layer is the same as a chemical element included in the substrate.

3. The element according to claim 2, wherein the chemical element is silicon.

4. The element according to claim 1, wherein the first electrode layer is provided on a third surface continued to the first surface and the second surface of the substrate.

5. The element according to claim 1, wherein
a through hole extending from the first surface of the substrate to the first metal layer is provided in the substrate and the insulating layer, and
the first electrode layer is in contact with the first surface of the substrate, an inner wall of the through hole, and the first metal layer.

6. The element according to claim 1, further comprising:
a second metal layer provided on the first surface of the substrate and in the through hole via the first electrode layer.

7. The element according to claim 1, further comprising:
a second electrode layer provided on the first semiconductor layer.

8. A method for manufacturing a semiconductor light emitting element, comprising:
forming a semiconductor light emitting unit on a first substrate via a buffer layer, the semiconductor light emitting unit including a first semiconductor layer of a first conductivity type, a second semiconductor layer of a second conductivity type, and a light emitting layer provided between the first semiconductor layer and the second semiconductor layer, and the first semiconductor layer being in contact with the buffer layer;
forming a first metal layer on the second semiconductor layer, the first metal layer being in contact with the second semiconductor layer;
forming an insulating layer on the first metal layer; and
bonding a second substrate to the insulating layer.

9. The method according to claim 8, wherein the bonding of the second substrate to the insulating layer is performed in an ambient atmosphere.

10. The method according to claim 8, wherein a surface of the insulating layer facing the second substrate is polished before bonding the second substrate to the insulating layer.

11. The method according to claim 10, wherein the polishing is performed by chemical mechanical polishing.

12. The method according to claim 8, further comprising, after bonding the first metal layer to the second substrate via the insulating layer:
removing the first substrate from the buffer layer;
removing the buffer layer from the first semiconductor layer;
forming a through hole extending from a first surface of the second substrate to the first metal layer in the second substrate and in the insulating layer; and
forming a first electrode layer in contact with the first surface of the substrate, an inner wall of the through hole, and the first metal layer.

13. The method according to claim 8, wherein a chemical element included in the insulating layer is the same as a chemical element included in the substrate.

14. The method according to claim 13, wherein the chemical element is silicon.

15. A light emitting device comprising:
a casing; and
a semiconductor light emitting element provided in the casing, the semiconductor light emitting element including:
a substrate having a first surface and a second surface on opposite side from the first surface;
an insulating layer provided on the second surface of the substrate;
a first metal layer provided on the insulating layer;
a semiconductor light emitting unit provided on the first metal layer and including a first semiconductor layer of a first conductivity type, a second semiconductor layer of a second conductivity type, and a light emitting layer provided between the first semiconductor layer and the second semiconductor layer, the second semiconductor layer being electrically connected to the first metal layer; and
a first electrode layer provided on the first surface of the substrate, extending in the substrate and in the insulating layer, and electrically connected to the first metal layer.

16. The device according to claim 15, wherein a chemical element included in the insulating layer is the same as a chemical element included in the substrate.

17. The device according to claim 16, wherein the chemical element is silicon.

18. The device according to claim 15, wherein the first electrode layer is provided on a third surface continued to the first surface and the second surface of the substrate.

19. The device according to claim 15, wherein
a through hole extending from the first surface of the substrate to the first metal layer is provided in the substrate and in the insulating layer, and
the first electrode layer is in contact with the first surface of the substrate, an inner wall of the through hole, and the first metal layer.

20. The device according to claim 15, further comprising:
a second metal layer provided on the first surface of the substrate and in the through hole via the first electrode layer.
